(19) United States
(12) Patent Application Publication
(10) Pub. No.: US 2011/0204511 A1
(43) Pub. Date: Aug. 25, 2011

(54) System and Method for Improving Reliability of Integrated Circuit Packages

(75) Inventors: Stanley Craig BEDDINGFIELD, McKinney, TX (US); Orlando Florendo TORRES, Richardson, TX (US); Robert Fabian McCARTHY, Dallas, TX (US)

(73) Assignee: TEXAS INSTRUMENTS INCORPORATED, Dallas, TX (US)

(21) Appl. No.: 13/099,055

(22) Filed: May 2, 2011

Related U.S. Application Data
(63) Continuation of application No. 11/948,924, filed on Nov. 30, 2007.

(51) Int. Cl. H01L 23/48

(52) U.S. Cl. 257/737; 257/E23.141

(57) ABSTRACT

An integrated circuit package includes a die, a bump, an underbump metallization layer formed between the bump and the die, a portion of the underbump metallization layer under the bump having a first radius, and a redistribution layer formed between the underbump metallization layer and the die. The redistribution layer has a pad positioned under the underbump metallization layer. The pad has a second radius, and makes contact with the underbump metallization layer. The second radius is less than or equal to the first radius. The integrated circuit package also includes a first dielectric layer disposed between the die and the redistributing layer.

### TECHNICAL FIELD

The present invention relates generally to a system and method for integrated circuits, and more particularly to a system and method for improving reliability of integrated circuit packages.

### BACKGROUND

A wafer-level chip scale package (WCSP) enables the electrical and mechanical connection of several integrated circuit dies into a system on a chip (SOC) without the use of a die carrier or package. The integrated circuit dies in a WCSP may be directly connected to one another or to a printed wiring board or ceramic or silicon substrate with electrical connections on the integrated circuit dies being made through conductive balls or bumps formed on the integrated circuit die surface. Individual integrated circuit dies may be connected using flip chip connection techniques to enable further reductions in an overall size of the WCSP. Therefore, a WCSP may be physically smaller in volume than an alternately packaged SOC with a similar number of integrated circuit dies since the alternately packaged SOC may make use of die carriers and/or not make use of flip chip connection techniques.

In a typical WCSP, a build-up material may be used to create a package structure to help ensure that good electrical and mechanical connections within the package structure, between the various integrated circuit dies are made and maintained. In addition to physically binding the integrated circuit dies together, the build-up material may also be used as a dielectric and as a means of providing a layer for the conductive connections (usually solder balls or bumps). Examples of a build-up material may be polyimide, including linear polyimides and aromatic polyimides, and benzocyclobutene (BCB). The build-up material made from a polyimide, BCB, and so forth, may enable a degree of flexibility that may help to prevent the breaking of electrical and mechanical bonds due to differences in thermal expansion of the variety of materials used in the WCSP as well as the circuit board, module or substrate to which the WCSP is connected.

Although the use of a build-up material may provide a degree of flexibility that may help to prevent the breakage of electrical and mechanical bonds, as the size of the integrated circuits and/or the number of ball or bump connections used in a WCSP increases, the operating temperature range expands, and a frequency of the temperature cycle increases. As a result, the differences in the expansion of the different materials in the WCSP may exceed the ability of the build-up material to absorb the resulting stresses on the balls/bumps, and cracks may appear in the build-up material, consequently, some of the electrical and mechanical bonds may break.

### SUMMARY OF THE INVENTION

These and other problems are generally solved or circumvented, and technical advantages are generally achieved, by embodiments of a system and a method for improving reliability of integrated circuit packages.

In accordance with an embodiment, an integrated circuit package is provided. The integrated circuit package includes a die and a first dielectric layer. The die includes a bump, an underbump metallization layer formed between the bump and the die with a portion of the underbump metallization layer under the bump having a first radius, and a redistribution layer formed between the underbump metallization layer and the die, the redistribution layer having a pad positioned under the underbump metallization layer, the pad having a second radius, and the pad making contact with the underbump metallization layer, wherein the second radius is smaller than or equal to the first radius. The first dielectric layer disposed between the die and the redistribution layer.

In accordance with another embodiment, an integrated circuit package is provided. The integrated circuit package includes a first die, a second die, and a plurality of solder balls. The first die includes a first plurality of bumps and a second plurality of bumps, an underbump metallization layer formed between the first plurality of bumps and the second plurality of bumps and the first die, and a redistribution layer, formed between the underbump metallization layer and the first die. A portion of the underbump metallization layer under each bump has a radius. The redistribution layer has a pad positioned under each portion of the underbump metallization layer formed under each bump, each pad having a radius, and each pad making electrical contact with the portion of the underbump metallization layer, wherein each pad has a radius that is larger than or equal to a radius of portion of the underbump metallization layer.

In accordance with another embodiment, a method of manufacturing an integrated circuit is provided. The method includes forming a first insulating layer over a first integrated circuit die, the first insulating layer having a first open portion, exposing a portion of the first integrated circuit die, forming a redistribution layer over the first insulating layer, the redistribution layer having a pad electrically coupled to the portion of the first integrated circuit die and a signal trace coupled to the pad, and forming a second insulating layer over the redistribution layer, the second insulating layer having a second open portion, exposing the pad. The method also includes forming a metallization layer over the second insulating layer, the metallization layer having a contact forming an electrical connection with the pad, and forming a bump over the contact of the metallization layer. The method further includes attaching a second integrated circuit die, wherein a portion of the second integrated circuit die makes electrical contact with the bump.

An advantage of an embodiment is that board level reliability of a WCSP may be increased without requiring the use of alternate or thicker materials. Furthermore, current manufacturing processes may not need to be altered, thereby increased board level reliability may be achieved with very little or no impact on the WCSP or to its assembly to a printed wiring board, module or substrate.

The foregoing has outlined rather broadly the features and technical advantages of the present invention in order that the detailed description of the embodiments that follow may be better understood. Additional features and advantages of the embodiments will be described hereinafter which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the embodiments, and the advantages thereof, reference is now made to the following descriptions taken in conjunction with the accompanying drawings, in which:

FIG. 1a is a diagram of a side view of a portion of a WCSP;

FIG. 1b is a diagram of a side view of a portion of a WCSP mounted on a printed wire board;

FIG. 2a is a diagram of a top view of the WCSP;

FIG. 2b is a diagram of a pad in a redistribution layer showing mechanical stress;

FIGS. 3a and 3b are diagrams of side and top views of a portion of a WCSP;

FIGS. 4a and 4b are diagrams of side and top views of a portion of a WCSP;

FIG. 5 is a diagram of a typical signal trace routing for a WCSP;

FIG. 6 is a diagram of a signal trace routing for a WCSP with reduced mechanical stress;

FIGS. 7a and 7b are diagrams of WCSPs;

FIG. 8 is a diagram of a sequence of events in the fabrication of a WCSP;

FIG. 9 is a diagram of a sequence of events in increasing board level reliability of a WCSP; and

FIGS. 10a and 10b are diagrams of data plots of peeling stress for different WCSP configurations.

### DETAILED DESCRIPTION OF ILLUSTRATIVE EMBODIMENTS

The making and using of the embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The embodiments will be described in a specific context, namely a wafer-level chip scale package containing a number of integrated circuit dies. The invention may also be applied, however, to other packaged systems on a chip where there may be concern for board level reliability due to differences in thermal expansion potentially leading to breakage of electrical and mechanical connections.

With reference now to FIG. 1a, there is shown a diagram illustrating a portion of a WCSP 100. FIG. 1a displays a portion of the WCSP 100 where an electrical/mechanical connection is made on an integrated circuit die. A bump 105 is shown on a substrate 110 of a first integrated circuit die. An underbump metallization layer 115 may electrically couple the bump 105 to a redistribution layer 120. The redistribution layer 120 may enable a routing of electrical connections formed on the substrate 110 to a location compatible with a second integrated circuit die, or to wire bond pads spaced along a periphery of the first integrated circuit die. The redistribution layer 120 includes a pad (not shown) that enables the electrical connection of the underbump metallization layer 115 to the redistribution layer 120. A dielectric layer 125 formed from a build-up material such as a polyimide (linear polyimide or aromatic polyimide, for example) or benzocyclobutene (BCB) may be used to provide mechanical support for the bump 105, the underbump metallization layer 115, and the redistribution layer 120.

The dielectric layer 125 may be formed from multiple individual layers of the material used to create the dielectric layer 125. For example, as shown in FIG. 1, the dielectric layer 125 may be formed from a first dielectric layer 126 and a second dielectric layer 127. The multiple layers of the dielectric layer 125 may be created at different times during the fabrication of the WCSP 100. For example, the first dielectric layer 126 may be created prior to the creation of the redistribution layer 120 and the second dielectric layer 127 may be created after the creation of the redistribution layer 120, underbump metallization layer 115 or after the creation of the bump 105.

Also shown in FIG. 1 a are cracks 130 in the dielectric layer 125. The cracks 130 may form between the substrate 110 and the redistribution layer 120 or between the redistribution layer 120 and the underbump metallization layer 115, for example. The cracks 130 may also form when the various materials in the WCSP 100 and a printed wire board expand at different rates due to differences in their coefficients of thermal expansion. Once the cracks 130 form and propagate, electrical and mechanical connections may become unreliable. This may lead to failure of the WCSP 100.

FIG. 1b displays a simplified side view of a WCSP 100 mounted on a printed wire board 150. The WCSP 100 includes a first integrated circuit die 155 and a second integrated circuit die 160. The second integrated circuit die 160 may be electrically connected to the first integrated circuit die 155 via bumps 105. The bumps 105 may also enable the electrical connection of the integrated circuit die 155 as well as other integrated circuits (directly or indirectly) to the printed wire board 150 via bond wires 165.

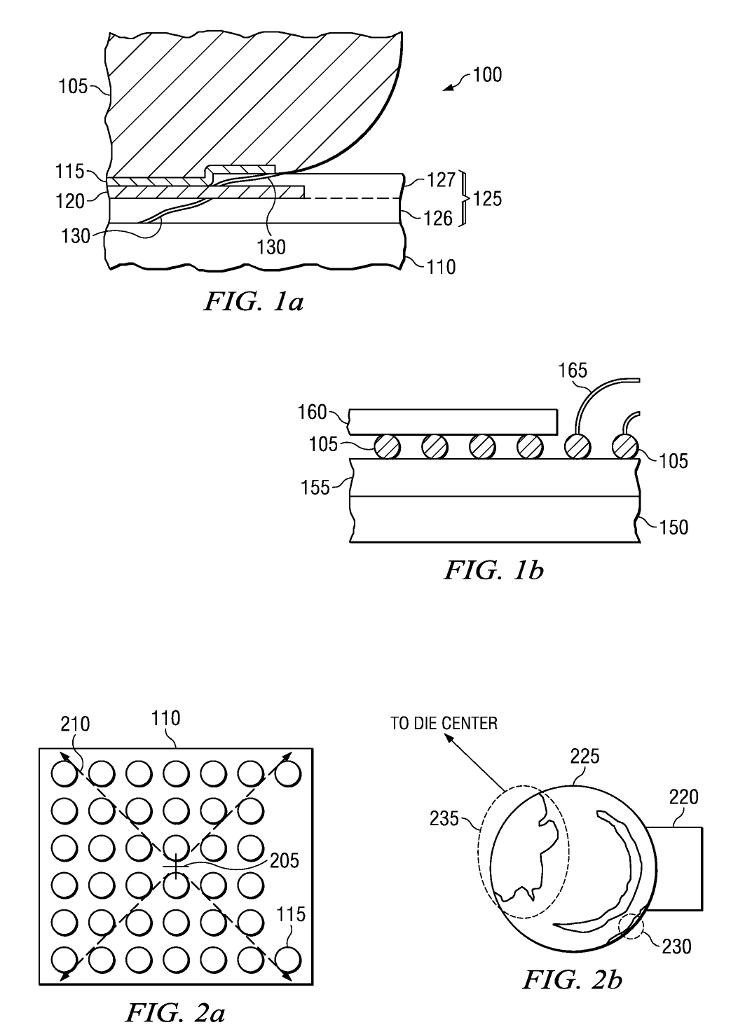

FIG. 2a illustrates a top view of the substrate 110 of the WCSP 100. Shown are portions of the underbump metallization layer 115 corresponding to bumps 105. The differences in the expansion and contraction of the materials in the WCSP 100 may lead to mechanical stress that is not constant over the surface of the substrate 110. The mechanical stress may be lowest at about the center of an integrated circuit die (shown at cross 205) and may increase as distance from the middle of the integrated circuit die increases. Maximum mechanical stress may be realized at bumps furthest away from the middle of the integrated circuit die, such as bump 115. This is shown in FIG. 2a as lines of increasing mechanical stress 210. The mechanical stress may increase in a radial manner away from the middle of the integrated circuit die.

Furthermore, the mechanical stress may differ within a pad of the redistribution layer 120. FIG. 2b illustrates a diagram of mechanical stress in the redistribution layer 120, with different highlighted regions illustrating different areas of mechanical stress. The redistribution layer 120 may include a trace portion 220 and a pad 225. The mechanical stress may be greatest at a point on the pad 225 furthest away from the middle of the integrated circuit die (shown as highlight 230) while the mechanical stress may be at its lowest at a point on the pad 225 closest to the middle of the integrated circuit die (shown as highlight 235).

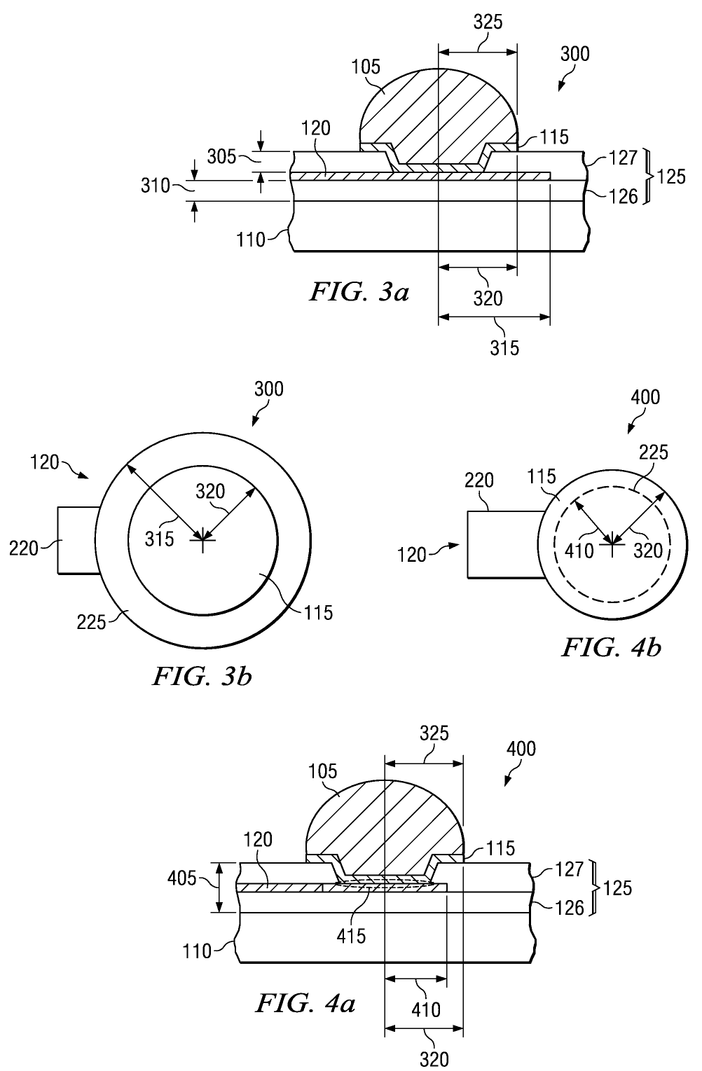

FIGS. 3a and 3b illustrate side and top views of a portion of a WCSP 300. The diagram shown in FIG. 3a displays typical material thicknesses of the dielectric layer 125 between the redistribution layer 120 and the underbump metallization layer 115 (shown as line 305) and the substrate 110 and the redistribution layer 120 (shown as line 310). As shown in FIG. 1a, the portion of the dielectric layer 125 between the redistribution layer 120 and the substrate 110 may be referred to as a first dielectric layer 126, while the portion of the dielectric layer 125 between the redistribution layer 120 and the underbump metallization layer 115 may be referred to as a second dielectric layer 127. Also shown is a radius 315 of the pad 225 of the redistribution layer 120 and the radius 320 of the underbump metallization layer 115. The bump 105 may also have a radius 325. The diagram shown in FIG. 3b displays the relative dimensions of the radius of the redistribution layer 120 and the radius of the underbump metallization layer 115.

Since the radius 315 of the pad 225 is significantly larger than the radius 320 of the underbump metallization layer 115, there may be a substantial portion of the dielectric layer 125 between the redistribution layer 120 and the underbump metallization layer 115. Since the portion of the dielectric layer 125 between the redistribution layer 120 and the underbump metallization layer 115 may be relatively thin (shown as line 305), it may not be mechanically strong. A relatively simple technique that may be used to increase the mechanical strength of the portion of the dielectric layer 125 between the redistribution layer 120 and the underbump metallization layer 115 may be to increase the thickness. However, this may increase the overall thickness of the WCSP 300. Other limiting factors affecting the thickness of the dielectric layer 125 may include excess substrate bowing and/or a reduction in dimensional resolution of the redistribution layer 120.

Another technique that may be used to increase thickness of the portion of the dielectric layer 125 between the redistribution layer 120 and the underbump metallization layer 115 may be to reduce the size of the pad 225. FIGS. 4a and 4b illustrate side and top views of a portion of a WCSP 400. The diagram shown in FIG. 4a displays a typical material thickness of the dielectric layer 125 between the substrate 110 and the underbump metallization layer 115 (shown as line 405). Also shown are typical values of the radius of the pad 225 of the redistribution layer 120 (shown as radius 410) and the radius of the underbump metallization layer 115 (shown as radius 320). In addition to being smaller than the radius of the underbump metallization layer 115, the radius of the pad 225 may also be smaller than the radius of the bump 105. The radius of the pad 225 is preferably about the size of a portion of the underbump metallization layer 115 making electrical contact with the pad 225, shown as highlight 415. Alternatively, the pad 225 may be slightly larger than the portion of the underbump metallization layer 115 making electrical contact with the pad 225. The diagram shown in FIG. 4b displays the relative dimensions of the radius of the redistribution layer 120 and the radius of the underbump metallization layer 115.

Unlike the WCSP 300, the size of the pad 225 in the WCSP 400 may have been reduced so that the radius of pad 225 is less than the radius of the underbump metallization layer 115. The reduction in the radius of the pad 225 may increase the effective thickness of the dielectric layer 125 between the substrate 110 and the underbump metallization layer 115 (line 405). The increased thickness of the dielectric layer 125 may increase the mechanical strength of the dielectric layer 125, making it more resistant to cracks induced by mechanical stress.

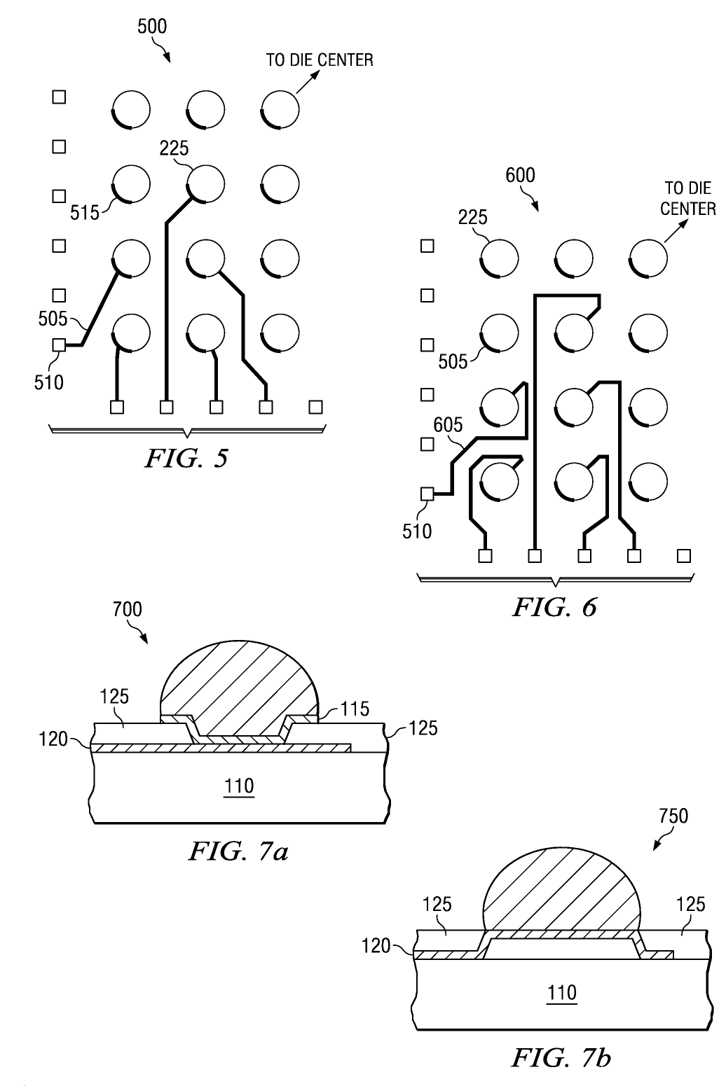

FIG. 5 illustrates a typical signal trace routing diagram for a WCSP 500. Signal traces in the redistribution layer 120, such as signal trace 505, typically are routed from peripheral wirebond pads directly to the pads 225 under the bump 105, using a direct connection (shortest length) approach. As a result, the signal trace 505 connecting the pad 225 to an input/output pad 510, usually located around a periphery of the integrated circuit die, typically connects to the pad 225 at a point on the bump furthest from the integrated circuit die center. Unfortunately, this is normally the point of highest mechanical stress on the pad 225, shown as dark region 515 on the pad 225. The increased mechanical stress may help to increase the probability of a mechanical failure at the connection point between the pad 225 and the signal trace 505.

FIG. 6 illustrates an exemplary trace routing diagram for a WCSP 600. Rather than routing signal traces in the redistribution layer 120 with minimal signal trace length, signal traces may be routed to reduce mechanical stress at a connection point between bumps and the signal traces. For example, a signal trace 605 connecting the input/output pad 510 to the pad 225 may be routed to a portion of the pad 225 with lower mechanical stress rather than to a portion of the pad 225 that is closest to the input/output pad 510. As shown, the signal trace 605 may be routed to a side of the pad 225 that is closer to the center of the integrated circuit die.

FIGS. 7a and 7b illustrate side views of alternate embodiments of WCSPs. The diagram shown in FIG. 7a illustrates a WCSP 700 wherein the dielectric layer 125 underneath the redistribution layer 120 has been eliminated to help reduce a potential area wherein cracks may develop. The diagram shown in FIG. 7b illustrates a WCSP 750 wherein the redistribution layer 120 may also be used as the underbump metallization. This eliminates the underbump metallization layer 115, such as shown in FIG. 7a. The elimination of the underbump metallization layer 115 may help to reduce the formation of cracks in the dielectric layer 125 due to the elimination a material with a potentially different coefficient of thermal expansion, which may lead to reduced mechanical stress.

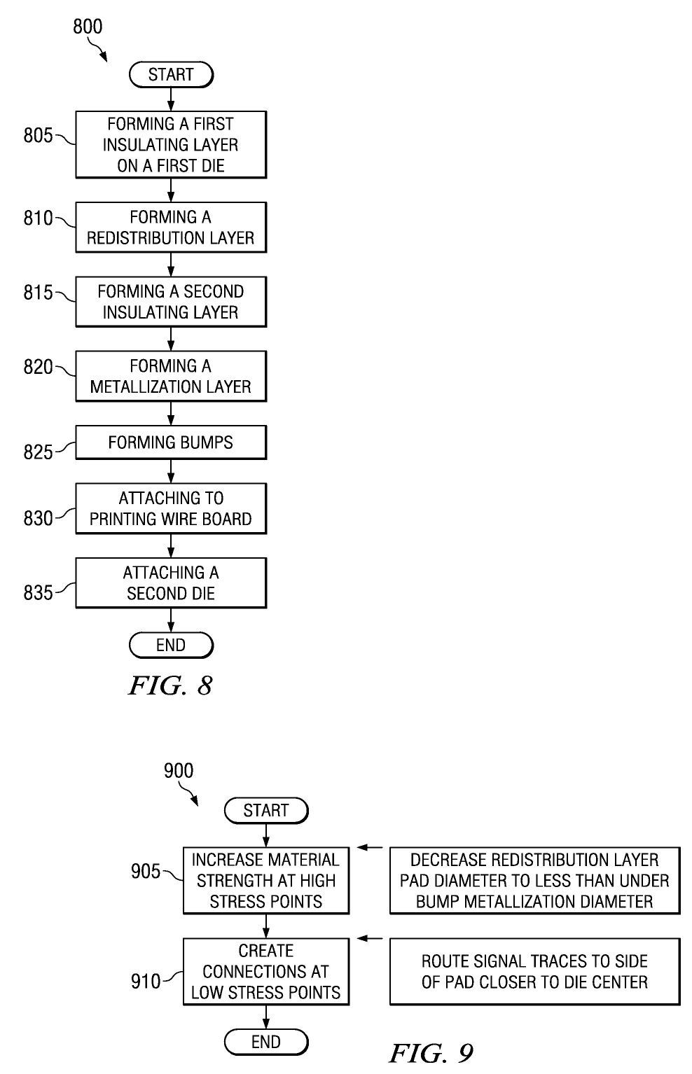

FIG. 8 illustrates a sequence of events 800 in the fabrication of a WCSP. The fabrication of a WCSP may begin with a formation of a first insulating layer (or dielectric layer) on a first integrated circuit die (block 805). The first insulating layer may be made from a polyimide or BCB and may be formed by standard spinning or printing and etching techniques such as those involving the coating of the first integrated circuit die with the polyimide or BCB, curing the polyimide or BCB, and then using photoresist and etching techniques to remove unwanted portions of the polyimide or BCB. After the first insulating layer has been formed, a redistribution layer may be formed (block 810). The redistribution layer may be formed by creating a thin film layer of a metallic material over the first integrated circuit die, which may have been at least partially covered by the first insulating film. The redistribution layer may be formed by sputter deposition techniques followed by plating and etching, for example.

After the redistribution layer has been formed, a second insulating layer may be formed (block 815). The second insulating layer may be used to prevent electrical short circuits in the redistribution layer and may have openings to permit electrical connectivity where desired. The second insulating layer may be created using techniques similar to those used in the forming of the first insulating layer (block 805). Then, a metallization layer may be formed over the second insulating layer (block 820). The metallization layer may be formed in a manner similar to the formation of the redistribution layer (block 810). The metallization layer may enable the formation of bumps (block 825) that may be used to attach additional integrated circuit dies or solder balls to permit electrical connectivity with circuitry external to the WCSP. The bumps may be created by depositing solder over portions of the metallization layer. The WCSP may then be attached to a printed wire board, module or other substrate (block 830).

The second integrated circuit die may be attached to the printed wire board, module, or substrate using flip chip or surface mounting techniques (block 835). In other applications, a second integrated circuit die may be attached to the WCSP where the second integrated circuit die may be flipped so that a surface of the second integrated circuit die containing integrated circuitry is facing a surface of the first integrated circuit die containing integrated circuitry. Alternatively, the second integrated circuit die may be mounted so that the surface of the second integrated circuit die containing integrated circuitry is facing away from the surface of the first integrated circuit die containing integrated circuitry and bond wires may be used to make electrical connections. The fabrication of the WCSP may then continue with operations such as encapsulating the backside of the WCSP to provide a measure of protection for the WCSP, testing the WCSP, and so forth.

FIG. 9 illustrates a sequence of events 900 in increasing the board level reliability of a WCSP. The board level reliability of a WCSP may be a function of cracks developing in the WCSP due to thermal stress arising from different material expansion rates as the WCSP undergoes thermal cycling. A particular problem area that may be prone to the development of stress cracks is in the dielectric layer 125, wherein a material, such as polyimide or BCB, may be used as an electrical and mechanical insulator. As the WCSP undergoes temperature cycling, the various components of the WCSP, such as the integrated circuit dies and the dielectric layer 125, may expand at different rates depending on their coefficients of thermal expansion. The differences in the expansion may lead to the formation of stress cracks.

Several techniques may be utilized to help reduce the formation of stress cracks. It may be possible to increase material strength at high stress points (block 905). For example, an alternate material may be used in place of polyimide or BCB in the dielectric layer 125. However, if polyimide or BCB must be used, it may be possible to increase material strength by increasing the thickness of the dielectric layer 125 at the high stress points. One way to increase the thickness is to decrease the redistribution layer pad diameter so that the diameter is smaller than the diameter of the underbump metallization layer, as shown in FIGS. 4a and 4b.

In addition to increasing material strength at high stress points to help reduce the formation of stress cracks that may lead to electrical connection failure, it may be possible to further increase board level reliability by creating electrical connections at low (or relatively low) stress points (block 910). For example, due to typical arrangement of a WCSP, shortest path signal trace routing normally places electrical connections between a signal trace and a bump at high stress points, as shown in FIG. 5. However, by using non-shortest path signal trace routing, it may be possible to place electrical connections between a signal trace and a bump at points of lower stress, such as shown in FIG. 6.

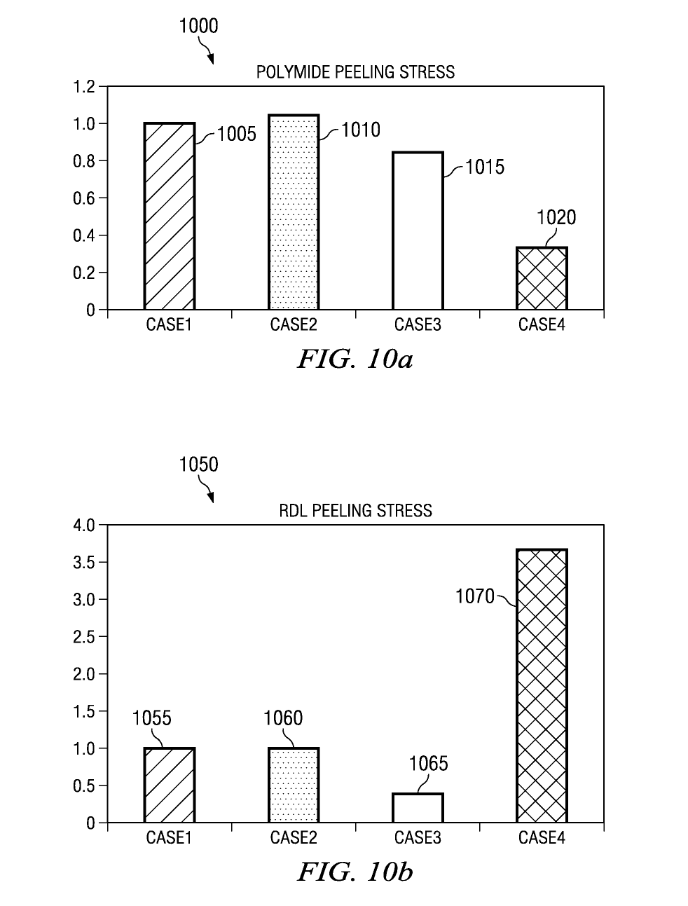

The combination of increasing material strength and utilizing a non-shortest path signal trace routing technique may help to increase board level reliability. FIGS. 10a illustrates a data plot 1000 of polyimide/underbump metallization layer 115 peeling stress for several different arrangements of the dielectric layer 125/redistribution layer 120 of a WCSP. A first trace 1005 illustrates polyimide/underbump metallization layer 115 peeling stress for an arrangement of the dielectric layer 125/redistribution layer 120 as shown in FIGS. 3a and 3b, a second trace 1010 illustrates polyimide/underbump metallization layer 115 peeling stress for an arrangement of the dielectric layer 125/redistribution layer 120 as shown in FIG. 7a, a third trace 1015 illustrates polyimide/underbump metallization layer 115 peeling stress for an arrangement of the dielectric layer 125/redistribution layer 120 as shown in FIGS. 4a and 4b, and a fourth trace 1020 illustrates polyimide/underbump metallization layer 115 peeling stress for an arrangement of the dielectric layer 125/redistribution layer 120 as shown in FIG. 7b. The polyimide/underbump metallization layer 115 peeling stress is measurably lower for the dielectric layer 125/redistribution layer 120 arrangement as shown in FIGS. 4a and 4b (the third trace 1015), and significantly lower for the dielectric layer 125/redistribution layer 120 arrangement as shown in FIG. 7b (the fourth trace 1020).

FIG. 10b illustrates a data plot 1050 of redistribution layer 120 peeling stress for several different arrangements the dielectric layer 125/redistribution layer 120 of a WCSP. A fifth trace 1055 illustrates redistribution layer 120 peeling stress for an arrangement of the dielectric layer 125/redistribution layer 120 as shown in FIGS. 3a and 3b, a sixth trace 1060 illustrates redistribution layer 120 peeling stress for an arrangement of the dielectric layer 125/redistribution layer 120 as shown in FIG. 7a, a seventh trace 1065 illustrates redistribution layer 120 peeling stress for an arrangement of the dielectric layer 125/redistribution layer 120 as shown in FIGS. 4a and 4b, and an eighth trace 1070 illustrates redistribution layer 120 peeling stress for an arrangement of the dielectric layer 125/redistribution layer 120 as shown in FIG. 7b. The redistribution layer 120 peeling stress is significantly lower for the dielectric layer 125/redistribution layer 120 arrangement as shown in FIGS. 4a and 4b (the seventh trace 1065), while significantly higher for the dielectric layer 125/redistribution layer 120 arrangement as shown in FIG. 7b (the eighth trace 1070).

Although the embodiments and their advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An integrated circuit package comprising:
an integrated circuit die having a center point;
a redistribution layer (RDL) on the integrated circuit die including a pad portion and a trace portion, in which the trace connects the pad on a first end and routes to a periphery of the die on a second end;
the pad having a first area of greatest mechanical stress farthest from the center point of the die and a second area of lowest mechanical stress closest to the center point of the die; and
the trace connecting the pad at a location farther from the first area than from the second area.

2. The integrated circuit package of claim 1, further comprising a conductive bump connected to the RDL pad.

3. The integrated circuit package of claim 2, further comprising an underbump metallization (UBM) layer between the RDL and the conductive bump.

4. The integrated circuit package of claim 3, in which the UBM layer and the pad are of disk shape and are concentric.

5. The integrated circuit package of claim 1, further comprising a plurality of RDL pads at corner regions of the integrated circuit package, in which each of the plurality of pads has a first area of greatest mechanical stress farthest from the center point of the die and a second area of lowest mechanical stress closest to the center point of the die; and a trace connecting the pad at a location farther from the first area than from the second area.

6. An integrated circuit package comprising:
an integrated circuit die having a center point;
a redistribution layer (RDL) on the integrated circuit die including a plurality of pads at corner regions of the integrated circuit die and a plurality of traces, in which a trace connects a pad on a first end and routes to a peripheral bond pad on a second end;
each pad having a first half of periphery closest to the center point of the integrated circuit die and a second half of periphery farthest form the enter point of the integrated circuit die; and
each trace connecting the pad at the first half of the periphery.

7. The integrated circuit package of claim 6, further comprising a conductive bump connected to the RDL pad.

8. The integrated circuit package of claim 7, further comprising an underbump metallization (UBM) layer between the RDL and the conductive bump.

9. The integrated circuit package of claim 8, in which the UBM layer and the pad are of disk shape and are concentric.

10. An integrated circuit package comprising:
a wafer-level-chip-scale-package (WCSP) die having a center point;
a redistribution layer (RDL) on the integrated circuit die including a plurality of pads at corner regions of the die and a plurality of traces, in which a trace connects a pad on a first end and routes to a peripheral bond pad on a second end;
each pad having a first half of periphery closest to the center point of the die and a second half of periphery farthest form the enter point of the die; and
each trace connecting the pad at the first half of the periphery.

11. The integrated circuit package of claim 10, further comprising an underbump metallization (UBM) layer between the RDL and the conductive bump.
